(19) United States
(12) Patent Application Publication
(10) Pub. No.: US 2026/0255717 A1
(43) Pub. Date: Aug. 27, 2026

(54) WAVEGUIDE-TYPE VISIBLE AND NEAR-INFRARED PHOTODETECTOR STRUCTURE AND PREPARATION METHOD THEREOF

(71) Applicant: TROE PHOTONICS, HANGZHOU, LTD., Hangzhou (CN)

(72) Inventor: Ziqiang ZHAO, Hangzhou (CN)

(73) Assignee: TROE PHOTONICS, HANGZHOU, LTD., Hangzhou (CN)

(21) Appl. No.: 19/651,834

(22) Filed: Apr. 20, 2026

Related U.S. Application Data
(63) Continuation of application No. PCT/CN2024/125811, filed on Oct. 18, 2024.

(30) Foreign Application Priority Data
Nov. 6, 2023 (CN) 202311461549.6

(51) Int. Cl. H10F 71/00; H10F 30/221; H10F 30/223; H10F 39/10; H10F 77/00; H10F 77/1223; H10F 77/14; H10F 77/30; H10F 77/40

(52) U.S. Cl. CPC H10F 71/121; H10F 30/221; H10F 30/223; H10F 39/103; H10F 77/1223; H10F 77/147; H10F 77/148; H10F 77/334; H10F 77/413; H10F 77/935

(57) ABSTRACT

A waveguide-type visible and near-infrared photodetector structure and preparation method thereof are provided. The structure includes a dielectric layer, a cladding layer, an optical waveguide layer, an intermediate layer, and an electroabsorption layer from top to bottom; the electroabsorption layer and the dielectric layer are communicated through an optical-layer-to-electronic-layer via structure; the dielectric layer is made of a single-crystal or polycrystalline semiconductor material. The method enables the fabrication of a waveguide-type visible and near-infrared photodetector with large bandwidth and high sensitivity, and has the advantages of fewer process steps and a simple driving circuit design.

### CROSS REFERENCE TO THE RELATED APPLICATIONS

This application is a continuation application of International Application No. PCT/CN2024/125811, filed on Oct. 18, 2024, which is based upon and claims priority to Chinese Patent Application No. 202311461549.6, filed on Nov. 6, 2023, the entire contents of which are incorporated herein by reference.

### TECHNICAL FIELD

The present invention belongs to the field of semiconductor processes and devices, and particularly relates to a waveguide-type visible and near-infrared photodetector structure and preparation method thereof. The photodetector can be applied in fields such as visible and near-infrared communication, as well as visible and near-infrared sensing.

### BACKGROUND

The concept of integrated optics is based on the technology of micro-nano etching on planar substrates to form specific optical waveguide structures. For a long time, the research focus of integrated optics has been on the near-infrared band, including the O-band (1350 nm) and the C-band (1550 nm). Its representative platforms mainly include the II-VI compound semiconductor integrated optics platform, the III-V compound semiconductor integrated optics platform, the Group IV semiconductor integrated optics platform, and integrated optics platforms composed of various doped glass or polymer materials.

Glass materials represented by silicon nitride and silicon oxynitride exhibit excellent optical properties such as low optical loss and high environmental stability in integrated optics. However, such materials are only suitable for passive optical devices, and the integration of active optical devices is often achieved by coupling with external discrete optical devices via lenses or optical fibers.

With the development of semiconductor process technology, heterogeneous integration, as an advanced packaging technology, can stack chips in the form of chiplets to achieve direct interconnection between different functional chips. Furthermore, this technology can also be applied to the stacked interconnection of optical chips and electrical chips, and this type of optoelectronic interconnection known as Co-packaged Optics (CPO). A major challenge in CPO design is the compact integration of three modules: light source, optical modulation, and optical detection.

Photoelectric conversion, namely optical detection, is a crucial component in CPO systems, and there is an urgent need for an inexpensive and easily scalable device architecture. Traditional optical detection for the C/O band often relies on compound semiconductors, which are costly and incompatible with the existing silicon CMOS process, leading to numerous limitations. Shifting the focus to the visible and near-infrared band, photoelectric conversion can be realized by adopting Group IV semiconductor PN/PIN junctions, which feature fast response speed, high sensitivity, and abundant material resources. However, there are no waveguide-type visible light detectors based on Group IV semiconductor PIN junctions available on the market at present. The reason for this is that amorphous materials or epitaxial Group IV semiconductor materials are all used as light absorption materials, which result in a significant deterioration of device performance.

### SUMMARY

The present invention focuses on high-speed photoelectric conversion in the visible and near-infrared light wavebands, which can effectively overcome the inherent drawbacks such as low speed and low responsivity caused by traditional epitaxial growth or amorphous material deposition, and realize a waveguide-type visible and near-infrared photodetector with large bandwidth and high responsivity.

According to the first part of the present invention, a waveguide-type visible and near-infrared photodetector structure is provided, which includes, from top to bottom, a dielectric layer, a cladding layer, an optical waveguide layer, an intermediate layer, and an electroabsorption layer; where the electroabsorption layer and the dielectric layer are communicated through an optical-layer-to-electronic-layer via structure; the dielectric layer is made of a single-crystal or polycrystalline semiconductor material; optical signals propagate through a waveguide structure in the optical waveguide layer and reach the electroabsorption layer via coupling, the optical signals are converted into electrical signals via the electroabsorption layer, the electrical signals are conducted to the dielectric layer through the optical-layer-to-electronic-layer via structure, and the dielectric layer processes the received electrical signals.

Further, the electroabsorption layer is formed into a functional structure by pre-embedding a doped structure on the surface of an intrinsic Group IV semiconductor substrate wafer, followed by thinning and etching; the pre-embedded doped structure is a lateral semiconductor junction.

According to the second part of the present invention, to fabricate the waveguide-type visible and near-infrared photodetector structure as described in the first aspect, the preparation is carried out through the following steps:
S1: etching alignment marks on a surface of an intrinsic Group IV semiconductor substrate wafer;
S2: forming an intermediate layer on the intrinsic Group IV semiconductor substrate wafer;
S3: forming an electroabsorption layer on the surface of the intrinsic Group IV semiconductor substrate wafer through doping;
S4: forming an optical waveguide layer on the intermediate layer;
S5: forming a waveguide structure by etching the optical waveguide layer;
S6: forming a cladding layer on the optical waveguide layer and performing a planarization process;
S7: preparing a dielectric layer with electrode contacts, and communicating the dielectric layer and the electroabsorption layer through an optical-layer-to-electronic-layer via structure;
S8: performing a thinning process on a back of the intrinsic Group IV semiconductor substrate wafer; and
S9: etching a thinned intrinsic Group IV semiconductor substrate wafer to retain the electroabsorption layer.

Further, steps S1 and S2 are reversed, that is, the intermediate layer is first formed on the intrinsic Group IV semiconductor substrate wafer, and then the alignment marks are etched on the surface of the intrinsic Group IV semiconductor substrate wafer covered with the intermediate layer.

Further, the electroabsorption layer is formed on the intrinsic Group IV semiconductor substrate wafer through hole impurity doping and electron impurity doping; the electroabsorption layer forms a lateral semiconductor junction with a carrier concentration gradient through diffusion and/or ion implantation.

Further, the electroabsorption layer and the optical waveguide layer are directly integrated via the intermediate layer by means of wafer bonding.

Further, the waveguide structure of the optical waveguide layer can be formed from a single material, or by stacking multiple materials layer by layer from bottom to top or from inside to outside.

Further, the waveguide structure is first formed on the optical waveguide layer by etching, followed by formation and planarization of the cladding layer, and finally bonding to the dielectric layer via wafer bonding; the electroabsorption layer is then formed by thinning and etching; a device size of the electroabsorption layer on a wafer plane can be larger than a size of the underlying waveguide structure.

Further, a cladding structure is formed on the surface of the photodetector structure to achieve optical isolation and device passivation.

According to the third part of the present invention, the following preparation steps may also be adopted to fabricate the waveguide-type visible and near-infrared photodetector structure as described in the first aspect:
S1: etching alignment marks on a surface of an intrinsic Group IV semiconductor substrate wafer;
S2: forming an intermediate layer on the intrinsic Group IV semiconductor substrate wafer;
S3: forming an electroabsorption layer on the surface of the intrinsic Group IV semiconductor substrate wafer through doping;
S4: forming an optical waveguide layer on the intermediate layer;
S5: forming a cladding layer on the optical waveguide layer and performing a planarization process;
S6: preparing a dielectric layer with electrode contacts, and bonding the intrinsic Group IV semiconductor substrate wafer with the cladding layer formed thereon to the dielectric layer;
S7: performing a thinning process on a back of the intrinsic Group IV semiconductor substrate wafer;
S8: etching a thinned intrinsic Group IV semiconductor substrate wafer to retain the electroabsorption layer;
S9: forming a waveguide structure by etching the optical waveguide layer; and
S10: communicating the dielectric layer and the electroabsorption layer through an optical-layer-to-electronic-layer via structure.

Further, steps S1 and S2 are reversed, that is, the intermediate layer is first formed on the intrinsic Group IV semiconductor substrate wafer, and then the alignment marks are etched on the surface of the intrinsic Group IV semiconductor substrate wafer covered with the intermediate layer.

Further, the electroabsorption layer is formed on the intrinsic Group IV semiconductor substrate wafer through hole impurity doping and electron impurity doping; the electroabsorption layer forms a lateral semiconductor junction with a carrier concentration gradient through diffusion and/or ion implantation.

Further, the electroabsorption layer and the optical waveguide layer are directly integrated via the intermediate layer by means of wafer bonding.

Further, the waveguide structure of the optical waveguide layer can be formed from a single material, or by stacking multiple materials layer by layer from bottom to top or from inside to outside.

Further, the waveguide structure is not formed on the optical waveguide layer by etching; after formation of the cladding layer, the optical waveguide layer is bonded to the dielectric layer via wafer bonding; the electroabsorption layer is first defined into a photodetector structure by thinning and etching, and then the waveguide structure is formed on the optical waveguide layer to realize coupling of optical signals from the waveguide structure to the electroabsorption layer; a device size of the electroabsorption layer on a wafer plane is smaller than or equal to a size of the underlying waveguide structure.

Further, a cladding structure is formed on the surface of the photodetector structure to achieve optical isolation and device passivation.

The beneficial effects of the present invention are as follows: intrinsic silicon is introduced as the absorption material for the visible and near-infrared wavebands, which features higher crystal quality and better device performance compared with amorphous materials and epitaxial Group IV semiconductors. Moreover, the bandwidth and sensitivity of the device can be further optimized by adjusting the reserved thickness of the electroabsorption layer and the doping structure inside the electroabsorption layer.

### BRIEF DESCRIPTION OF THE DRAWINGS

FIG. 1 is a cross-sectional schematic view of the waveguide-type visible and near-infrared photodetector provided in the first part of the present disclosure;

FIG. 2 is a preparation flow chart of the waveguide-type visible and near-infrared photodetector provided in the second part of the present disclosure;

FIG. 3 is a structural schematic view of the preparation step S1 provided in the second part of the present disclosure;

FIG. 4 is a structural schematic view of the preparation step S2 provided in the second part of the present disclosure;

FIG. 5 is a structural schematic view of the preparation step S3 provided in the second part of the present disclosure;

FIGS. 6A-6B are schematic views of the possible structures of the electroabsorption layer in the preparation step S3 provided in the second part of the present disclosure;

FIG. 7 is a structural schematic view of the preparation step S4 provided in the second part of the present disclosure;

FIG. 8 is a structural schematic view of the preparation step S5 provided in the second part of the present disclosure;

FIG. 9 is a structural schematic view of the preparation step S6 provided in the second part of the present disclosure;

FIG. 10 is a structural schematic view of the preparation step S7 provided in the second part of the present disclosure;

FIG. 11 is a structural schematic view of the preparation step S8 provided in the second part of the present disclosure;

FIG. 12 is a structural schematic view of the preparation step S9 provided in the second part of the present disclosure.

FIG. 13 is a preparation flow chart of the waveguide-type visible and near-infrared photodetector provided in the third part of the present disclosure;

FIG. 14 is a structural schematic view of the preparation step S6 provided in the third part of the present disclosure;

FIG. 15 is a structural schematic view of the preparation step S8 provided in the third part of the present disclosure;

FIG. 16 is a structural schematic view of the preparation step S9 provided in the third part of the present disclosure;

FIGS. 17A-17B are top views of the tapered structures composed of the waveguide structure and the electroabsorption layer provided in the second and third parts of the present disclosure, respectively;

FIG. 18 is a structural schematic view of the preparation step S10 provided in the third part of the present disclosure.

In the figures, 100: intrinsic Group IV semiconductor substrate wafer, 101: electroabsorption layer, 102: intermediate layer, 103: optical waveguide layer, 104: cladding layer, 105: dielectric layer, 106: optical-layer-to-electronic-layer via structure, 301: alignment mark, 600: first-type hole-doped structure, 601: second-type hole-doped structure, 602: third-type hole-doped structure, 603: first-type electron-doped structure, 604: second-type electron-doped structure, 605: third-type electron-doped structure, and 801: waveguide structure.

### DETAILED DESCRIPTION OF THE EMBODIMENTS

As used herein, the term “substrate” refers to a material onto which subsequent material layers are deposited. The substrate itself can be patterned, and the material deposited on top of the substrate can either be patterned or remain unpatterned. In addition, the substrate can include a wide range of semiconductor materials such as silicon, germanium, gallium arsenide, indium phosphide and the like. Alternatively, the substrate can be composed of non-conductive materials such as glass, plastic, or sapphire wafers.

As used herein, the term “layer” refers to a portion of a material that includes a region with a defined thickness. A layer may extend over the entirety of an underlying or overlying structure, or may have an extent smaller than the extent of the underlying or overlying structure. Furthermore, a layer may be a region of a homogeneous or heterogeneous continuous structure, with a thickness less than the thickness of the continuous structure. For example, a layer may be located between any pair of horizontal planes between the top and bottom surfaces of a continuous structure, or at any pair of horizontal planes at the top and bottom surfaces of a continuous structure. A layer may extend horizontally, vertically, and/or along a tapered surface. A substrate may be a layer, may contain one or more layers therein, and/or may have one or more layers on, above, and/or below it. A layer may include multiple sublayers. For example, an interconnection layer may include one or more conductor and contact layers (in which interconnection lines and/or via contacts are formed) and one or more dielectric layers.

As used herein, the term “front side” of a structure refers to the surface of the structure on which a device is formed or is to be subsequently formed.

As used herein, the term “semiconductor” in reference to a structure refers to, but is not limited to, a material having a conductivity value falling between those of conductors and insulators. The material may be an elemental material or a compound material. A semiconductor may include, but is not limited to, elements, binary alloys, ternary alloys, and quaternary alloys. A structure formed using one or more semiconductors may include a single semiconductor material, two or more semiconductor materials, a single-component semiconductor alloy, two or more discrete-component semiconductor alloys, and semiconductor alloys that grade from a first semiconductor alloy to a second semiconductor alloy. A semiconductor may be undoped (intrinsic), hole-doped, electron-doped, doped with a gradient from a first doping level of one type to a third doping level of the same type, or doped with a gradient from a first doping level of one type to a third doping level of a different type.

As used herein, the term “metal” in reference to a structure refers to, but is not limited to, a material (elemental substance, compound or alloy) that exhibits excellent electrical and thermal conductivity as a result of the ready loss of its outer-shell electrons. Such materials may include, but are not limited to, gold, chromium, aluminum, silver, platinum, nickel, copper, rhodium, palladium, tungsten, and combinations of such materials.

As used herein, the terms “optical waveguide”, “dielectric waveguide”, or “waveguide” in reference to a structure refer to, but are not limited to, a dielectric medium or a combination of media that supports the propagation of optical signals within a predetermined wavelength range and maintains a fixed propagation direction as design. An optical waveguide may be at least one of the following: including at least a core and a cladding (e.g., an optical fiber), being formed as part of a carrier, and being an isolated structure and optical waveguide formed in a substrate (e.g., a planar lightwave circuit, a photonic integrated circuit, an integrated optical device). This includes, but is not limited to, flexible optical waveguides formed from molded glass, molded doped quartz, molded chalcogenide glass, and polymers. This further includes, but is not limited to, optical waveguides formed on the following substrates: silica-on-insulator, silica-on-silicon, silicon oxynitride-on-silicon, polymer-on-silicon, polymer-on-polymer, and the like.

As used herein, the term “optical waveguide layer” refers to a portion of a material that includes a region with a defined thickness. More specifically, it can be processed subsequently to have the function of confining optical waves within a specific cross-sectional range and conducting them in a planar plane, and may consist of one or more layers of waveguide materials, without limitation.

As used herein, the term “dielectric layer” refers to a portion of a material that includes a region with a defined thickness. More specifically, it has the function of realizing electrical connection or transporting carriers, and may consist of one or more layers of metal or other conductive materials, without limitation.

As used herein, the term “optical-layer-to-electronic-layer via structure” refers to a via structure connecting the dielectric layer and the electroabsorption layer, which functions to conduct the electrical connections in the dielectric layer and the electrical connections in the electroabsorption layer, enabling the electrons generated by the conversion of light in the electroabsorption layer to be further transmitted to the dielectric layer for subsequent signal processing. The materials thereof include, but are not limited to, the aforementioned metallic materials or conductive polymer materials.

To make the above objects, features, and advantages of the present invention more clearly and easily understood, the specific implementations of the present invention will be described in detail below with reference to the drawings.

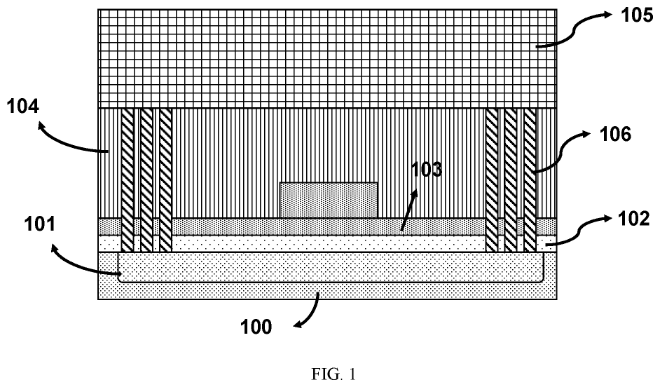

As shown in FIG. 1, the embodiment of the first part of the present disclosure provides a waveguide-type visible and near-infrared photodetector structure, which includes, from top to bottom, the dielectric layer 105, the cladding layer 104, the optical waveguide layer 103, the intermediate layer 102, and the electroabsorption layer 101. Optical signals propagate through the waveguide structure 801 in the optical waveguide layer 103 and reach the electroabsorption layer 101 via coupling. The doped structure in the electroabsorption layer 101 is optimized to ensure the high-speed operation of the photodetector. The optical signals are converted into electrical signals via the electroabsorption layer 101, and the electrical signals are conducted to the dielectric layer 105 through the optical-layer-to-electronic-layer via structure 106, where the dielectric layer 105 processes the received electrical signals. In the entire structure, the electroabsorption layer 101 is formed into a predetermined shape from the intrinsic Group IV semiconductor substrate wafer 100 by thinning and etching. The electroabsorption layer 101 is formed by pre-embedding a doped structure, and then a signal loop is constructed by the optical-layer-to-electronic-layer via structure 106. This avoids the inevitable problems such as crystal quality defects when growing Group IV semiconductor materials with visible light band absorption capacity (e.g., silicon and germanium) on dielectric materials, thus realizing the fabrication of a waveguide-type photodetector based on single-crystal materials.

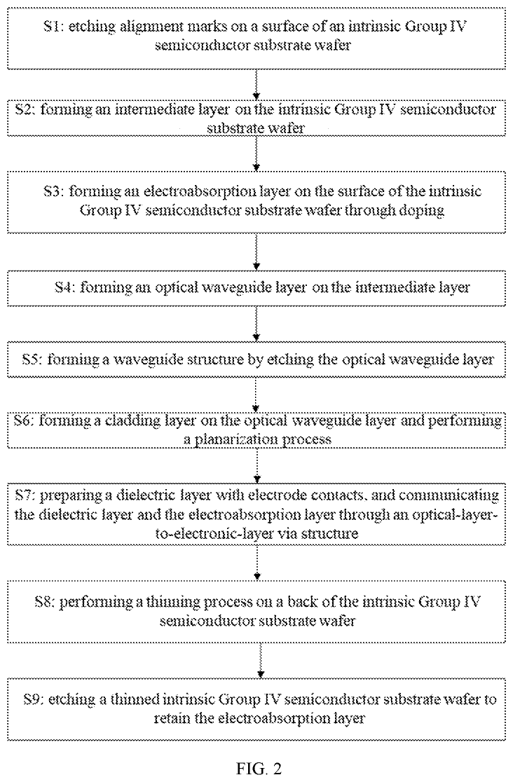

In the embodiments of the second part of the present disclosure, a preparation method of a waveguide-type visible and near-infrared photodetector structure is provided, which, as shown in FIG. 2, includes the following steps:

S1: The alignment marks 301 are etched on the surface of the intrinsic Group IV semiconductor substrate wafer 100 to facilitate subsequent process operations;

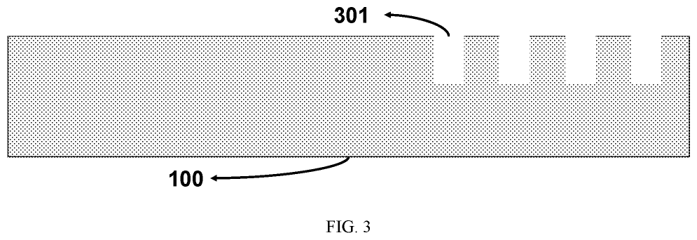

Specifically, for the purposes of realizing electron/hole doping, thinning to a predetermined thickness, and forming a predetermined shape of the electroabsorption layer 101 in the subsequent steps, the alignment marks 301 need to be reserved in advance. As shown in FIG. 3, the alignment marks 301 are prepared by forming corresponding patterns through photolithography or electron beam lithography, followed by etching to form groove structures, where the etching depth can be designed in the range of 0.2-10 μm according to the thinning process.

S2: The intermediate layer 102 is formed on the intrinsic Group IV semiconductor substrate wafer 100;

Further, the intermediate layer 102 can be formed by coating organic or inorganic adhesive, high-temperature thermal oxidation/nitridation, or deposition/sputtering, with a thickness ranging from 0.01 to 0.5 μm;

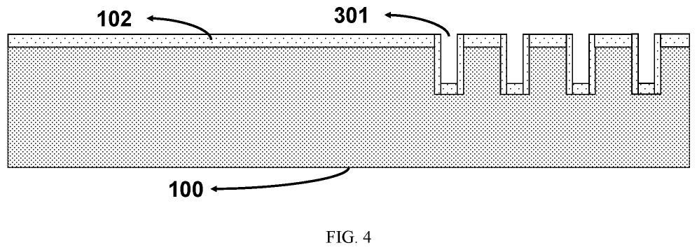

Preferably, in this embodiment, the intermediate layer 102 is formed by depositing a silicon oxide thin film, with a thickness of 0.05 μm, as shown in FIG. 4.

Further, the above steps S1 and S2 can be reversed, that is, the intermediate layer 102 is first formed on the intrinsic Group IV semiconductor substrate wafer 100, and then the alignment marks 301 are etched on the surface of the intrinsic Group IV semiconductor substrate wafer 100 covered with the intermediate layer 102.

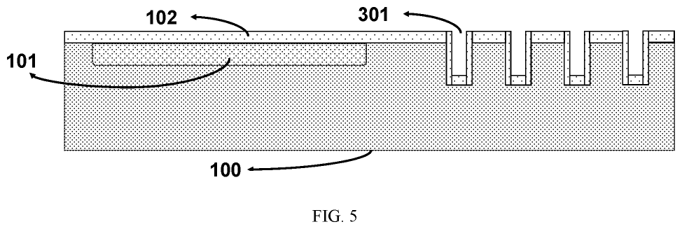

S3: As shown in FIG. 5, the electroabsorption layer 101 is formed on the surface of the intrinsic Group IV semiconductor substrate wafer 100 through hole impurity doping and electron impurity doping;

Further, the electroabsorption layer 101 can form a lateral semiconductor junction with a certain carrier concentration gradient through diffusion and/or ion implantation;

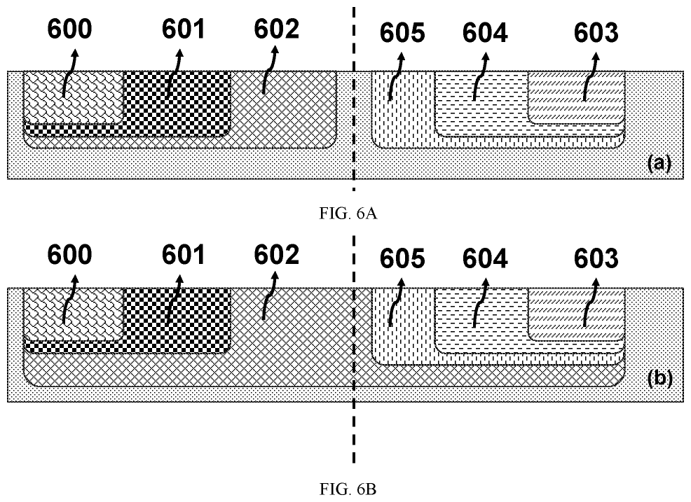

As shown in FIGS. 6A-6B, two possible semiconductor junction structures with a certain carrier concentration gradient are presented, which are included in the electroabsorption layer 101. Among them, the first-type hole-doped structure 600 is of p-type with a concentration of 10²⁰-10²¹ cm⁻³, the second-type hole-doped structure 601 is of p-type with a concentration of 10¹⁸-10²⁰cm⁻³, and the third-type hole-doped structure 602 is of p-type with a concentration of 10¹⁷-10¹⁹ cm⁻³. The first-type electron-doped structure 603 is of n-type with a concentration of 10²⁰-10²¹ cm⁻³, the second-type electron-doped structure 604 is of n-type with a concentration of 10¹⁸-10²⁰ cm⁻³, and the third-type electron-doped structure 605 is of n-type with a concentration of 10¹⁷-10¹⁹ cm⁻³.

As shown in FIG. 6A, the first-type hole-doped structure 600 is enclosed in the second-type hole-doped structure 601, the second-type hole-doped structure 601 in turn is enclosed in the third-type hole-doped structure 602. Similarly, the first-type electron-doped structure 603 is enclosed in the second-type electron-doped structure 604, the second-type electron-doped structure 604 in turn is enclosed in the third-type electron-doped structure 605. A certain distance exists between the third-type hole-doped structure 602 and the third-type electron-doped structure 605, and the distance should be ensured to be in the range of 0-2 μm to form a PIN junction, where the selection of the distance directly affects the bandwidth of the finally formed photodetector. Preferably, in this embodiment, the distance is 0.2 μm. The central axis of the waveguide structure 801 shown in the figure should be located between the third-type hole-doped structure 602 and the third-type electron-doped structure 605.

As shown in FIG. 6B, the first-type hole-doped structure 600 is enclosed in the second-type hole-doped structure 601, the second-type hole-doped structure 601 in turn is enclosed in the third-type hole-doped structure 602. The first-type electron-doped structure 603 is enclosed in the second-type electron-doped structure 604, the second-type electron-doped structure 604 in turn is enclosed in the third-type electron-doped structure 605, and the third-type electron-doped structure 605 is further enclosed in the third-type hole-doped structure 602. In this structure, the third-type electron-doped structure 605 and the third-type hole-doped structure 602 form a PN junction, and the third-type hole-doped structure 602 encloses the position of the central axis of the waveguide structure 801 with a range larger than the range of the waveguide structure 801. The reverse is also true.

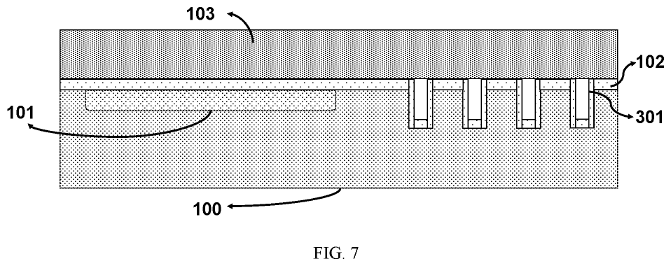

S4: As shown in FIG. 7, the optical waveguide layer 103 is formed on the intermediate layer 102;

Further, the optical waveguide layer 103 can be prepared by various methods, including deposition/sputtering, grinding or peeling after wafer bonding, etc.;

Further, the optical waveguide layer 103 is composed of a single material, and the stacked structure of multiple materials from bottom to top or from inside to outside is also included in the composition forms of the optical waveguide layer 103;

Preferably, in this embodiment, the optical waveguide layer 103 is made of silicon nitride with a thickness ranging from 0.4 to 1 μm.

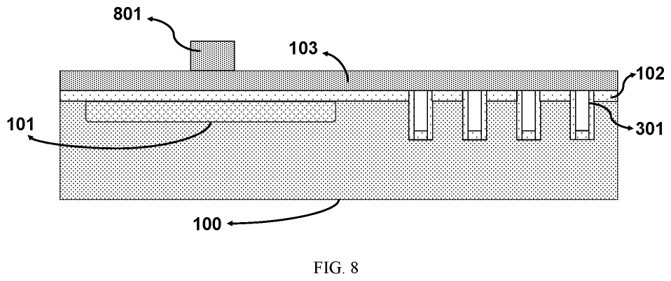

S5: As shown in FIG. 8, the waveguide structure 801 is formed by etching the optical waveguide layer 103;

Further, the waveguide structure 801 in the optical waveguide layer 103 is composed of at least one optical material, and the layer-by-layer stacked or cladded structure formed by a special method is also included in the composition forms of the waveguide structure 801 in the optical waveguide layer 103;

Preferably, in this embodiment, the thickness of the silicon nitride in the optical waveguide layer 103 after etching is 0.2-0.5 μm.

Preferably, in this embodiment, the width of the waveguide structure 801 is in the range of 0.4-2 μm.

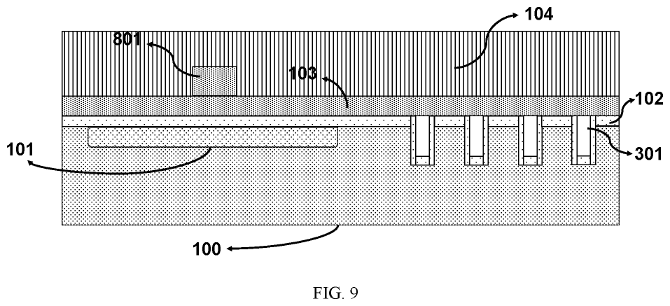

S6: As shown in FIG. 9, the cladding layer 104 is formed on the optical waveguide layer 103 and a planarization process is performed;

Further, the cladding layer 104 can be prepared by various methods, including deposition/sputtering, coating of organic or inorganic adhesive, etc.;

Preferably, in this embodiment, the cladding layer 104 is made of silicon oxide with a thickness ranging from 0.4 to 2 μm.

Preferably, in this embodiment, the thickness of the cladding layer 104 is 1 μm.

Further, the planarization process can be realized by controlling the coating and repairing process of organic or inorganic adhesive, or by chemical mechanical polishing;

Preferably, in this embodiment, the planarization of the cladding layer 104 is realized by chemical mechanical polishing.

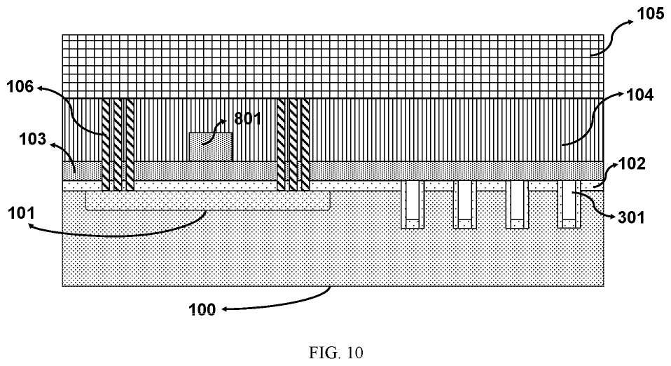

S7: As shown in FIG. 10, the dielectric layer 105 with electrode contacts is prepared, and the dielectric layer 105 and the electroabsorption layer 101 are communicated through the optical-layer-to-electronic-layer via structure 106;

Further, the optical-layer-to-electronic-layer via structure 106 can be prepared by etching, and the conductive filling material in the via holes can be formed by deposition, sputtering, or electroplating.

Further, the dielectric layer 105 can connect the pre-reserved electrode contacts on the dielectric layer 105 with the optical-layer-to-electronic-layer via structure 106 through solder welding or metal bonding.

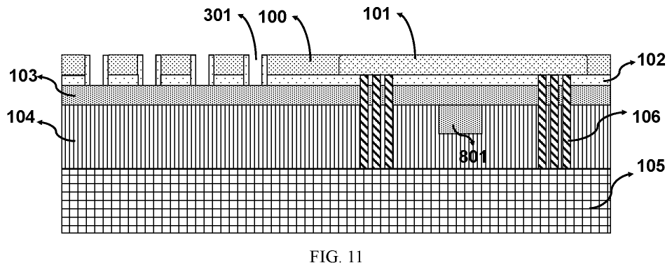

S8: As shown in FIG. 11, a thinning process is performed on the back of the intrinsic Group IV semiconductor substrate wafer 100;

Preferably, the thickness of the intrinsic Group IV semiconductor substrate wafer 100 after thinning is 0.1-0.5 μm.

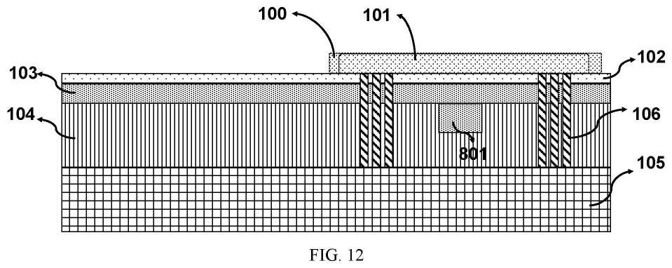

S9: As shown in FIG. 12, the thinned intrinsic Group IV semiconductor substrate wafer 100 is etched to retain the electroabsorption layer 101.

Preferably, a tapered coupling method should be adopted to enable the light in the waveguide structure 801 to be coupled to the electroabsorption layer 101 step by step.

Preferably, a cladding structure can be formed again on the electroabsorption layer 101 to achieve device passivation, and the material thereof can be the same as the material of the cladding layer 104.

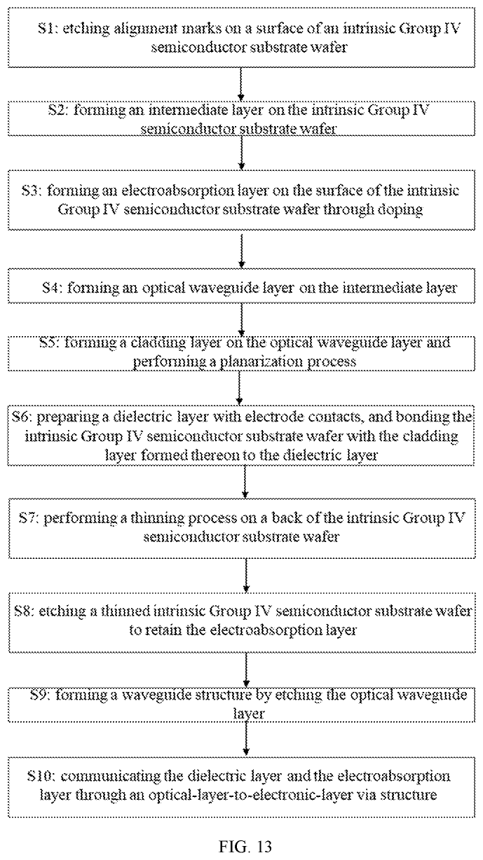

In the embodiments of the third part of the present disclosure, the preparation process may be adjusted such that the dielectric layer 105 is first bonded to the optical waveguide layer 103 without the waveguide structure 801 formed thereon, where the optical waveguide layer 103 has been transferred onto the intrinsic Group IV semiconductor substrate wafer 100 with the electroabsorption layer 101 formed thereon. The cladding layer 104 is formed on the optical waveguide layer 103, and a layered structure composed of the electroabsorption layer 101, the intermediate layer 102, the optical waveguide layer 103, the cladding layer 104, and the dielectric layer 105 from top to bottom is formed via polymer bonding or molecular force bonding, as shown in FIG. 13. The specific steps are as follows:

S1: The alignment marks 301 are etched on the surface of the intrinsic Group IV semiconductor substrate wafer 100 to facilitate subsequent process operations;

S2: The intermediate layer 102 is formed on the intrinsic Group IV semiconductor substrate wafer 100;

Further, the intermediate layer 102 can be formed by coating organic or inorganic adhesive, high-temperature thermal oxidation/nitridation, or deposition/sputtering;

S3: The electroabsorption layer 101 is formed on the surface of the intrinsic Group IV semiconductor substrate wafer 100 through hole impurity doping and electron impurity doping;

Further, the electroabsorption layer 101 can form a lateral semiconductor junction with a certain carrier concentration gradient through diffusion and/or ion implantation;

S4: The optical waveguide layer 103 is formed on the intermediate layer 102;

Further, the optical waveguide layer 103 can be prepared by various methods, including deposition/sputtering, grinding or peeling after wafer bonding, etc.;

Further, the optical waveguide layer 103 is composed of at least one optical material, and a layer-by-layer stacked or cladded structure formed by a special method is also included in the composition forms of the optical waveguide layer;

S5: The cladding layer 104 is formed on the optical waveguide layer 103 and a planarization process is performed;

Further, the cladding layer 104 can be prepared by various methods, including deposition/sputtering, coating of organic or inorganic adhesive, etc.;

Further, the planarization process can be realized by controlling the coating and repairing process of organic or inorganic adhesive, or by chemical mechanical polishing;

S6: The intrinsic Group IV semiconductor substrate wafer 100 with the cladding layer 104 formed thereon is bonded to the dielectric layer 105;

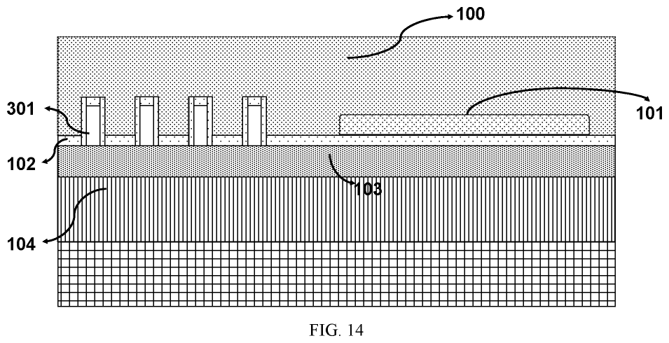

Further, during bonding, the side of the intrinsic Group IV semiconductor substrate wafer 100 with the cladding layer 104 shall be bonded to the side of the dielectric layer 105 with electrode contacts formed thereon, as shown in FIG. 14;

Further, no conductive materials are in contact between the two sides during bonding, and the material of the contact interface can be the same as or different from the material of the intermediate layer 102;

S7: A thinning process is performed on the back of the intrinsic Group IV semiconductor substrate wafer 100;

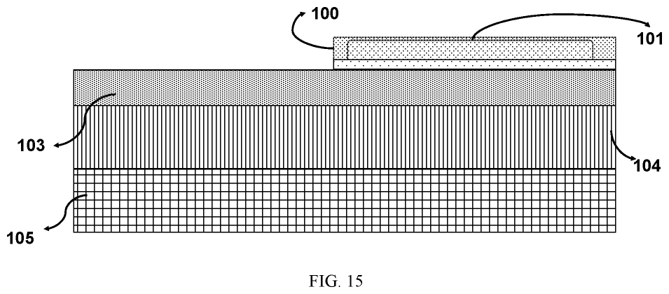

S8: The thinned intrinsic Group IV semiconductor substrate wafer 100 is etched to retain the electroabsorption layer 101, as shown in FIG. 15;

S9: The waveguide structure 801 is formed by etching the optical waveguide layer 103; Further, the waveguide structure 801 in the optical waveguide layer 103 is composed of at least one optical material, and a layer-by-layer stacked or cladded structure formed by a special method is also included in the composition forms of the waveguide structure 801 in the optical waveguide layer 103;

Further, the optical waveguide layer 103 is composed of a single material, and the stacked structure of multiple materials from bottom to top or from inside to outside is also included in the composition forms of the optical waveguide layer 103;

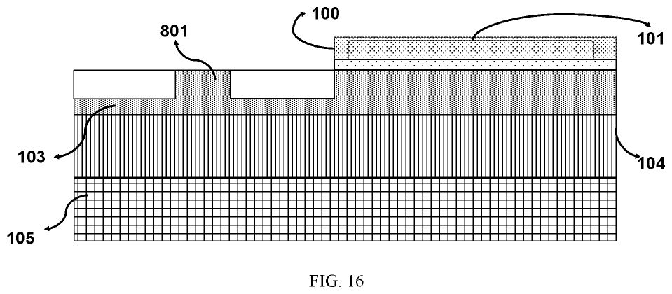

As shown in FIG. 16, the waveguide structure 801 is formed on the optical waveguide layer 103 by etching, with the cladding layer 104 disposed thereunder.

Further, a tapered structure adapted to the subsequent waveguide structure 801 is reserved on the electroabsorption layer 101 remaining on the intrinsic Group IV semiconductor substrate wafer 100 after thinning and etching.

In particular, for the tapered structure between the waveguide structure formed on the optical waveguide layer and the electroabsorption layer in the embodiments of the second part and the third part of the present disclosure, the stacking sequence of the optical waveguide layer and the electroabsorption layer shall be taken into account.

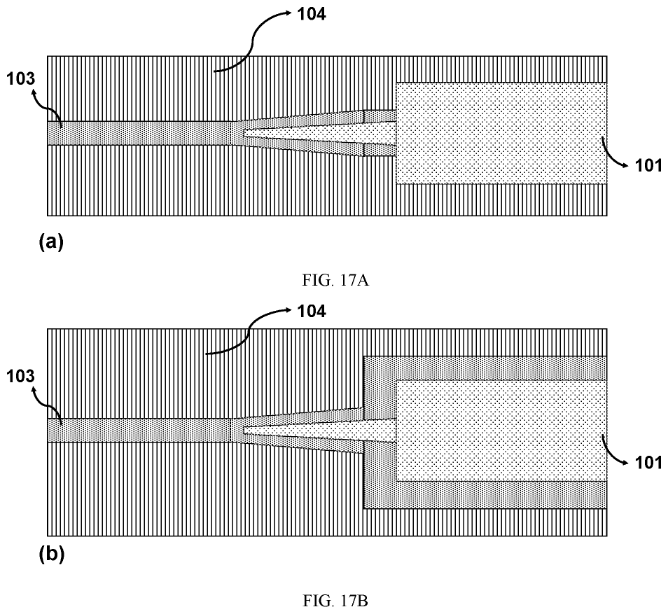

As shown in FIG. 17A, in the embodiments of the second part of the present disclosure, the waveguide structure 801 is first formed on the optical waveguide layer 103 by etching, followed by the formation and planarization of the cladding layer 104, and finally the bonding to the dielectric layer 105 via wafer bonding. The electroabsorption layer 101 is then formed by thinning and etching. Therefore, the device size of the electroabsorption layer 101 on the wafer plane can be larger than size of the underlying waveguide structure 801.

As shown in FIG. 17B, in the embodiments of the third part of the present disclosure, the waveguide structure 801 is not formed on the optical waveguide layer 103 by etching; after the formation of the cladding layer 104, the optical waveguide layer 103 is bonded to the dielectric layer 105 via wafer bonding. The electroabsorption layer 101 is first defined into a photodetector structure by thinning and etching, and then the waveguide structure 801 is formed on the optical waveguide layer 103 to realize the coupling of optical signals from the waveguide structure 801 to the electroabsorption layer 101. Therefore, the device size of the electroabsorption layer 101 on the wafer plane is smaller than or equal to the size of the underlying waveguide structure 801.

S10: The dielectric layer 105 and the electroabsorption layer 101 are communicated through the optical-layer-to-electronic-layer via structure 106;

Further, the optical-layer-to-electronic-layer via structure 106 can be prepared by etching, and the conductive filling material in the via holes can be formed by deposition, sputtering, or electroplating. The connection between the dielectric layer 105 and the optical-layer-to-electronic-layer via structure 106 can be realized by soldering or metal bonding;

The optical-layer-to-electronic-layer via structure 106 directly communicates the electroabsorption layer 101 and the dielectric layer 105 after etching and filling with conductive materials.

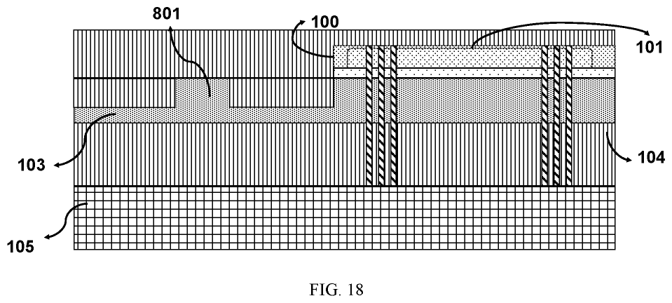

As shown in FIG. 18, the optical-layer-to-electronic-layer via structure 106 penetrates the electroabsorption layer 101 to communicate to the dielectric layer 105, and the electroabsorption layer 101 is finally covered with a cladding structure to achieve optical isolation and device passivation.

The above descriptions are merely the preferred embodiments of the present invention. Although the present invention has been disclosed above with preferred embodiments, it is not intended to limit the present invention. Any person skilled in the art may make numerous possible changes and modifications to the technical solution of the present invention, or modify it into equivalent embodiments with equivalent changes by using the disclosed methods and technical contents without departing from the scope of the technical solution of the present invention. Therefore, any simple modifications, equivalent changes and modifications made to the above embodiments based on the technical essence of the present invention without departing from the content of the technical solution of the present invention shall all fall within the protection scope of the technical solution of the present invention.

What is claimed is:

1. A waveguide-type visible and near-infrared photodetector structure, comprising, from top to bottom, a dielectric layer, a cladding layer, an optical waveguide layer, an intermediate layer, and an electroabsorption layer; wherein the electroabsorption layer and the dielectric layer are communicated through an optical-layer-to-electronic-layer via structure; the dielectric layer is made of a single-crystal or polycrystalline semiconductor material;
optical signals propagate through a waveguide structure in the optical waveguide layer and reach the electroabsorption layer via coupling, the optical signals are converted into electrical signals via the electroabsorption layer, the electrical signals are conducted to the dielectric layer through the optical-layer-to-electronic-layer via structure, and the dielectric layer processes the electrical signals.

2. The waveguide-type visible and near-infrared photodetector structure according to claim 1, wherein the electroabsorption layer is formed into a functional structure by pre-embedding a doped structure on a surface of an intrinsic Group IV semiconductor substrate wafer, followed by thinning and etching; the doped structure is a lateral semiconductor junction.

3. A preparation method of a waveguide-type visible and near-infrared photodetector structure, comprising the following steps:
S1: etching alignment marks on a surface of an intrinsic Group IV semiconductor substrate wafer;
S2: forming an intermediate layer on the intrinsic Group IV semiconductor substrate wafer;
S3: forming an electroabsorption layer on the surface of the intrinsic Group IV semiconductor substrate wafer through doping;
S4: forming an optical waveguide layer on the intermediate layer;
S5: forming a waveguide structure by etching the optical waveguide layer;
S6: forming a cladding layer on the optical waveguide layer and performing a planarization process;
S7: preparing a dielectric layer with electrode contacts, and communicating the dielectric layer and the electroabsorption layer through an optical-layer-to-electronic-layer via structure;
S8: performing a thinning process on a back of the intrinsic Group IV semiconductor substrate wafer; and
S9: etching a thinned intrinsic Group IV semiconductor substrate wafer to retain the electroabsorption layer.

4. The preparation method according to claim 3, wherein steps S1 and S2 are reversed, that is, the intermediate layer is first formed on the intrinsic Group IV semiconductor substrate wafer, and then the alignment marks are etched on the surface of the intrinsic Group IV semiconductor substrate wafer covered with the intermediate layer.

5. The preparation method according to claim 3, wherein the electroabsorption layer is formed on the surface of the intrinsic Group IV semiconductor substrate wafer through hole impurity doping and electron impurity doping; the electroabsorption layer forms a lateral semiconductor junction with a carrier concentration gradient through diffusion and/or ion implantation.

6. The preparation method according to claim 3, wherein the waveguide structure is first formed on the optical waveguide layer by etching, followed by formation and planarization of the cladding layer, and finally bonded to the dielectric layer via wafer bonding, and the electroabsorption layer is then formed by thinning and etching.

7. A preparation method of a waveguide-type visible and near-infrared photodetector structure, comprising the following steps:
S1: etching alignment marks on a surface of an intrinsic Group IV semiconductor substrate wafer;
S2: forming an intermediate layer on the intrinsic Group IV semiconductor substrate wafer;
S3: forming an electroabsorption layer on the surface of the intrinsic Group IV semiconductor substrate wafer through doping;
S4: forming an optical waveguide layer on the intermediate layer;
S5: forming a cladding layer on the optical waveguide layer and performing a planarization process;
S6: preparing a dielectric layer with electrode contacts, and bonding the intrinsic Group IV semiconductor substrate wafer with the cladding layer formed thereon to the dielectric layer;
S7: performing a thinning process on a back of the intrinsic Group IV semiconductor substrate wafer;
S8: etching a thinned intrinsic Group IV semiconductor substrate wafer to retain the electroabsorption layer;
S9: forming a waveguide structure by etching the optical waveguide layer; and
S10: communicating the dielectric layer and the electroabsorption layer through an optical-layer-to-electronic-layer via structure.

8. The preparation method according to claim 7, wherein steps S1 and S2 are reversed, that is, the intermediate layer is first formed on intrinsic Group IV semiconductor substrate wafer, and then the alignment marks are etched on the surface of the intrinsic Group IV semiconductor substrate wafer covered with the intermediate layer.

9. The preparation method according to claim 7, wherein the electroabsorption layer is formed on the surface of the intrinsic Group IV semiconductor substrate wafer through hole impurity doping and electron impurity doping; the electroabsorption layer forms a lateral semiconductor junction with a carrier concentration gradient through diffusion and/or ion implantation.

10. The preparation method according to claim 7, wherein the waveguide structure is not formed on the optical waveguide layer by etching at first; after formation of the cladding layer, the optical waveguide layer is bonded to the dielectric layer via wafer bonding; the electroabsorption layer is first defined into a photodetector structure by thinning and etching, and then the waveguide structure is formed on the optical waveguide layer by etching to realize coupling of optical signals from the waveguide structure to the electroabsorption layer; a photodetector size of the electroabsorption layer on a wafer plane is smaller than or equal to a size of the waveguide structure.
